(19) United States
(12) Patent Application Publication
(10) Pub. No.: US 2015/0381162 A1
(43) Pub. Date: Dec. 31, 2015

(54) LOW LEAKAGE ANALOG SWITCH

(71) Applicant: Zhengxiang Wang, Suzhou (CN)

(72) Inventor: Zhengxiang Wang, Suzhou (CN)

(21) Appl. No.: 14/555,563

(22) Filed: Nov. 26, 2014

(30) Foreign Application Priority Data
Jun. 25, 2014 (CN) 201410408825.7

(51) Int. Cl. H03K 17/16

(52) U.S. Cl. CPC H03K 17/161

(57) ABSTRACT

A semiconductor isolating switch has two series connected primary field effect transistors (FET), a first one the primary FETs is coupled between a first node and an intermediate node, and a second one of the primary FETs is coupled between the intermediate node and a second node. A controllable pull-up FET is coupled in series to a controllable pull-down FET. The controllable pull-up FET is coupled between a power rail node and a common node and the controllable pull-down FET is coupled between the common node and a ground rail node. A leakage control transistor is coupled between the common node and the intermediate node. The gates of all of the transistors are coupled to a switch control node.

### BACKGROUND OF THE INVENTION

The present invention relates generally to analog switches and, more particularly, to an isolating switch that isolates nodes between two circuits when one or both of the nodes have unknown, unpredictable or varying potentials.

When a Field Effect Transistor (FET) is in a non-conductive state it should not allow any current to flow between its drain and source terminals. However, in practice sub-threshold currents (leakage currents) may flow between the drain and source terminals even when the transistor has a gate to source voltage that biases the transistor to a non-conductive state. Consequently, FETs are not suitable for “ON” and “OFF” switching applications where small amounts of leakage current could cause malfunctioning or incorrect results, for instance, in sensitive instrumentation, tuning or monitoring circuits. Thus, it would be advantageous to have a circuit with a FET that prevents or reduces leakage currents.

### BRIEF DESCRIPTION OF THE DRAWINGS

The invention, together with objects and advantages thereof, may best be understood by reference to the following description of preferred embodiments together with the accompanying drawings in which:

FIG. 1 is a schematic circuit diagram of a semiconductor isolating switch according to an embodiment of the present invention;

FIG. 2 is a schematic circuit diagram of a semiconductor isolating switch according to another embodiment of the present invention;

FIG. 3 is a schematic circuit diagram of a semiconductor isolating circuit according to an embodiment of the present invention;

FIG. 4 is a schematic circuit diagram of a semiconductor isolating circuit according to yet another embodiment of the present invention; and

FIG. 5 is a schematic circuit diagram of an analog circuit according to an embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a semiconductor isolating switch having a first node, a second node, and a switch control node. There are two series connected primary FETs, where a first one the primary FETs is coupled between the first node and an intermediate node, and a second one of the primary FETs is coupled between the intermediate node and the second node. A controllable pull-up FET is coupled in series to a controllable pull-down FET. The controllable pull-up FET is coupled between a power rail node and a common node and the controllable pull-down FET is coupled between the common node and a ground rail node. A leakage control transistor is coupled between the common node and the intermediate node. The primary FETs, the controllable pull-up FET, the controllable pull-down FET, and the leakage control transistor each have a respective gate electrode coupled to the switch control node.

In another embodiment, the present invention provides an analog switch that includes a first circuit with a first circuit interconnecting node, and a second circuit with a second circuit interconnecting node. The analog switch selectively connects the first circuit interconnecting node to the second circuit interconnecting node. The analog switch also includes a first node coupled to the first circuit interconnecting node and a second node coupled to the second circuit interconnecting node. There are two series connected primary FETs, where a first one the primary FETs is coupled between the first node and an intermediate node, and a second one of the primary FETs is coupled between the intermediate node and the second node. A controllable pull-up FET is coupled in series to a controllable pull-down FET. The controllable pull-up FET is coupled between a power rail node and a common node and the controllable pull-down FET is coupled between the common node and a ground rail node. A leakage control transistor is coupled between the common node and the intermediate node. The primary FETs, the controllable pull-up FET, the controllable pull-down FET and the leakage control transistor each have a respective gate electrode coupled to a switch control node.

In yet another embodiment, the present invention provides an analog switch comprising two complementary semiconductor isolating switches, where each of the isolating switches includes a first node, a second node, and a switch control node. There are two series connected primary FETs, where a first one the primary FETs is coupled between the first node and an intermediate node, and a second one of the primary FETs is coupled between the intermediate node and the second node. A controllable pull-up FET is coupled in series to a controllable pull-down FET. The controllable pull-up FET is coupled between a power rail node and a common node and the controllable pull-down FET is coupled between the common node and a ground rail node. A leakage control transistor is coupled between the common node and intermediate node. The primary FETs, the controllable pull-up FET, the controllable pull-down FET, and the leakage control transistor each have a respective gate electrode coupled to the switch control node. The first nodes of each of the isolating switches are coupled together and the second nodes of each of the isolating switches are coupled together. Further, the switch control nodes of each of the isolating switches are coupled together by way of an inverter and each of the transistors of a first one of the switches is complementary relative to a respective transistor of a second one of the switches.

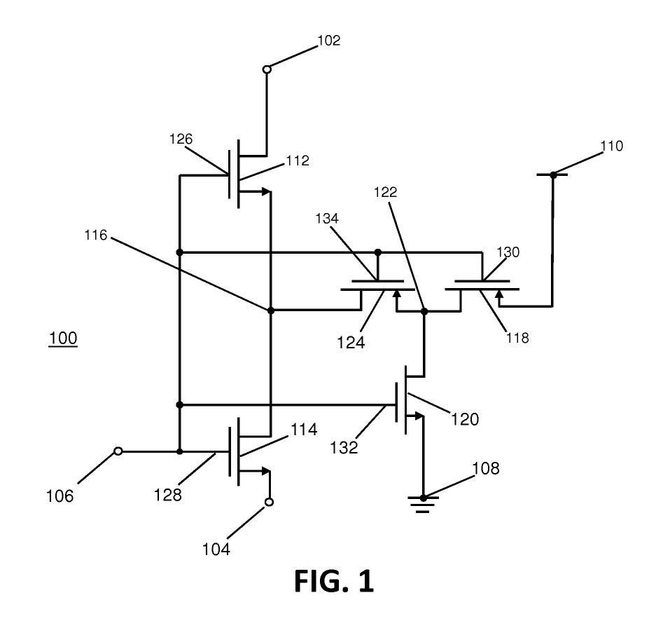

Referring now to FIG. 1, a schematic circuit diagram of a semiconductor isolating switch 100, according to an embodiment of the present invention, is shown. The switch 100 includes a first node 102, a second node 104, a switch control node 106, a ground rail node 108 and a power rail node 110. The switch 100 has two series connected primary FETs 112, 114. A first one the primary FETs 112 is coupled between the first node 102 and an intermediate node 116, and a second one of the primary FETs 114 is coupled between the intermediate node 116 and the second node 104.

A controllable pull-up FET 118 is coupled in series to a controllable pull-down FET 120. The controllable pull-up FET 118 is coupled between the power rail node 110 and a common node 122 and the controllable pull-down FET 120 is coupled between the common node 122 and the ground rail node 108.

The switch 100 also includes a leakage control transistor 124 coupled between the common node 122 and the intermediate node 116. Further, gate electrodes 126, 128 of the primary FETs 112, 114, gate electrodes 130, 132 of the controllable pull-up FET 118 and the controllable pull-down FET 120, and the gate electrode 134 of the leakage control transistor 124 are all coupled to the switch control node 106.

As shown, a source electrode of the first one the primary FETs 112 is coupled to the intermediate node 116 and a drain electrode of the second one of the primary FETs 114 is coupled to the intermediate node 116. In this particular embodiment, the primary FETs 112, 114 and the controllable pull-down FET 120 are N-type transistors, and the controllable pull-up FET 118 and the leakage control transistor 124 are both P-type transistors. Also, a source electrode of the leakage control transistor 124 is coupled to the common node 122 and a respective drain electrode of the controllable pull-up FET 118 and the controllable pull-down FET 120 are also coupled to the common node 122. As shown, the source electrode of the controllable pull-up FET 118 is coupled to the power rail node 110 and the source electrode of the controllable pull-down FET 120 is coupled to the ground rail node 108. This embodiment has the source electrode of the second one of the primary FETs 114 coupled to the second node 104, and a drain electrode of the first one of the FETs 112 coupled to the first node 102.

In operation, when a control signal at the switch control node 106 is at a ground potential (GND) the pull-up FET 118 and the leakage control transistor 124 couple the intermediate node 116 to a supply potential (VDD), thereby controlling the first one the primary FETs 112 to be in a non-conductive state. More specifically, the gate to source potential (Vgs) of the N-type transistor 112 is approximately GND-VDD, which alleviates or substantially eliminates sub-threshold leakage currents between the first and second nodes 102, 104. In contrast, when the control node 106 is at a supply potential (VDD), the pull-down FET 120 couples the common node 122 to ground (GND) and thus the leakage control transistor 124 is in an “OFF” or non-conductive state. The primary FETs 112, 114 can therefore operate in their conductive states without being affected by the other transistors 118, 120,124.

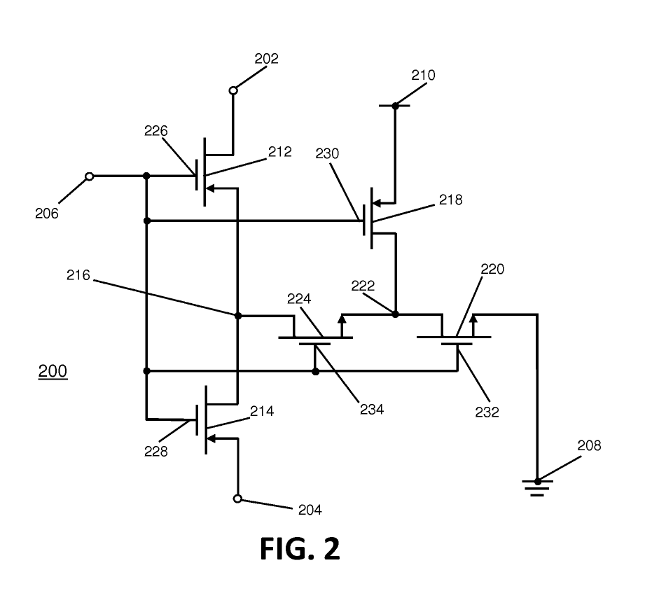

Referring now to FIG. 2, a schematic circuit diagram of a semiconductor isolating switch 200, according to another embodiment of the present invention, is shown. The switch 200 includes a first node 202, a second node 204, a switch control node 206, a ground rail node 208 and a power rail node 210. The switch 200 has two series connected primary FETs 212, 214 and a first one the primary FETs 212 is coupled between the first node 202 and an intermediate node 216 and a second one of the primary FETs 214 is coupled between the intermediate node 216 and the second node 204.

A controllable pull-up FET 218 is coupled in series to a controllable pull-down FET 220. The controllable pull-up FET 218 is coupled between the power rail node 210 and a common node 222 and the controllable pull-down FET 220 is coupled between the common node 222 and the ground rail node 208.

The switch 200 also includes a leakage control transistor 224 coupled between the common node 222 and intermediate node 216. The gate electrodes 226, 228 of the primary FETs 212, 214, gate electrodes 230, 232 of the controllable pull-up FET 218 and controllable pull-down FET 220, and the gate electrode 234 of the leakage control transistor 224 are all coupled to the switch control node 206.

As shown, a source electrode of the first one the primary FETs 212 is coupled to the intermediate node 216 and a drain electrode of the second one of the primary FETs 214 are coupled to the intermediate node 216. In this particular embodiment the primary FETs 212, 214 and the controllable pull-up FET 218 are P-type transistors, and the controllable pull-down FET 220 and leakage control transistor 224 are both N-type transistors. Also, a source electrode of the leakage control transistor 224 is coupled to the common node 222 and a respective drain electrode of the controllable pull-up FET 218 and the controllable pull-down FET 220 are also coupled to the common node 222. As shown, the source electrode of the controllable pull-up FET 218 is coupled to the power rail node 210 and the source electrode of the controllable pull-down FET 220 is coupled to the ground rail node 208. This embodiment also shows the source electrode of the second one of the primary FETs 214 being coupled to the second node 204, and a drain electrode of the first one of the FETs 212 being coupled to the first node 202.

In operation, when a control signal at the switch control node 206 is at a supply potential (VDD) the pull-down FET 220 and leakage control transistor 224 couple the intermediate node 216 to a ground potential (GND) thereby controlling the first one the primary FETs 212 to be in a non-conductive state. More specifically, the gate to source potential (Vgs) of P-type transistor 212 is approximately VDD-GND thus alleviating or substantially eliminating sub threshold leakage currents between first and second nodes 202, 204. In contrast, when the control node 206 is at a ground potential (GND) the pull-up FET 218 couples the common node 222 to the supply potential (VDD) and thus the leakage control transistor 224 is in an “OFF” or non-conductive state. The primary FETs 212, 214 can therefore function in their conductive states without being affected by the other transistors 218, 220, 224.

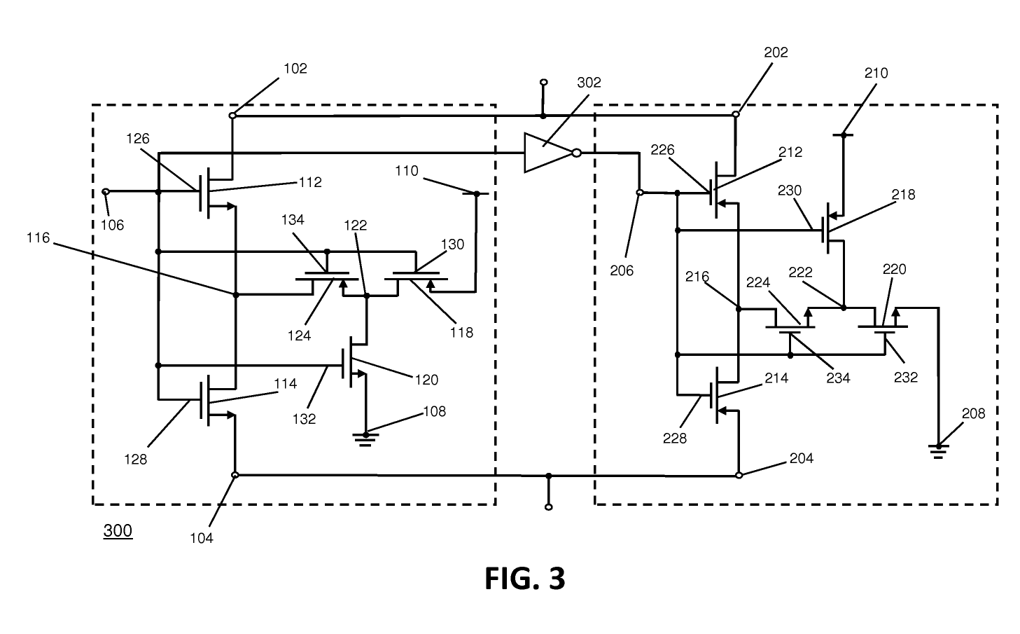

Referring now to FIG. 3, a schematic circuit diagram of a semiconductor isolating circuit 300, according to an embodiment of the present invention, is shown. The semiconductor isolating circuit 300 has two complementary semiconductor isolating switches which are the semiconductor isolating switch 100 and the semiconductor isolating switch 200. In this embodiment, the first nodes 102, 202 of each of the switches are coupled together, the second nodes of each of the switches 100, 200 are coupled together and the switch control nodes 106, 206 of each of the switches 102, 202 are coupled together through an inverter 302.

Each of the transistors of a first one of the semiconductor isolating switches is complementary relative to each respective transistor of a second one of the semiconductor isolating switches. More specifically, in this embodiment the two series connected primary FETs 112, 114, the controllable pull-down FET 120 of the first one of the switches 100 are N-type transistors, whereas the controllable pull-up FET 118 and the leakage control transistor 124 of the first one of the switches 100 are P-type transistors. In contrast, the two series connected primary FETs 212, 214, the controllable pull-up FET 218 of the second one of the switches 200 are P-type transistors, whereas the controllable pull-down FET 220 and leakage control transistor 224 of the second one of the switches 200 are N-type transistors.

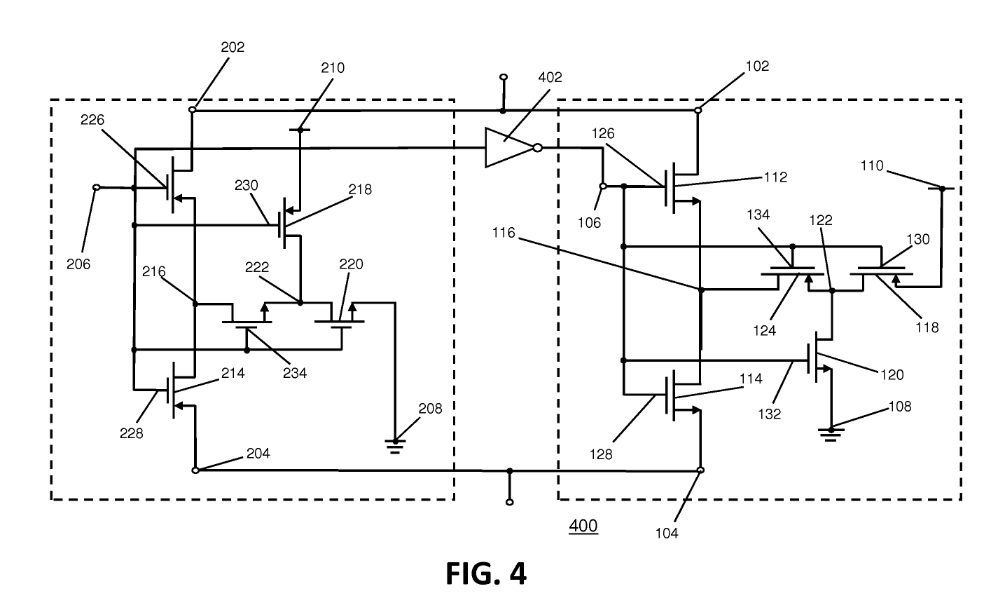

FIG. 4 is a schematic circuit diagram of a semiconductor isolating circuit 400, according to another embodiment of the present invention. The semiconductor isolating circuit 400 has two complementary semiconductor isolating switches which are the semiconductor isolating switch 100 and the semiconductor isolating switch 200. In this embodiment, the first nodes 102, 202 of each of the switches are coupled together, the second nodes of each of the switches are coupled together and the switch control nodes 106, 206 of each of the switches are coupled together through an inverter 402. Besides the polarity of the inverter all other elements of the semiconductor isolating circuit 400 are the same as the semiconductor isolating circuit 300.

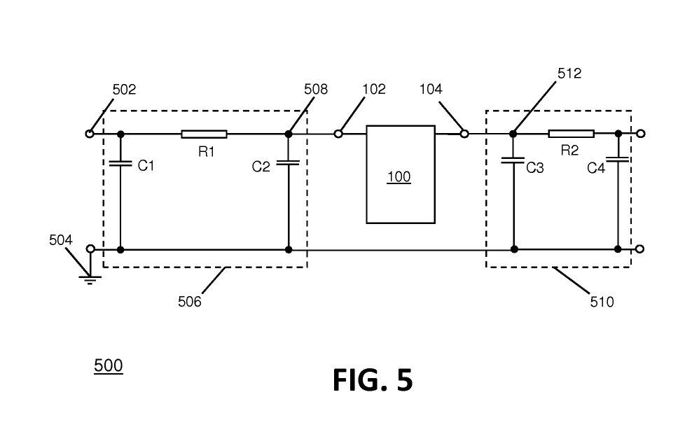

FIG. 5 is a schematic circuit diagram of an analog circuit 500 according to another embodiment of the present invention. The analog circuit 500 includes first and second analog circuit nodes 502, 504 that may be power and ground rails as will be apparent to a person skilled in the art. There is a first circuit 506 with a first circuit interconnecting node 508. By way of example, the first circuit 506 is formed from a first capacitor C1 across the analog circuit nodes 502, 504. A series connected resistor R1 and capacitor C2 are also coupled across the analog circuit nodes 502, 504. In this embodiment the first circuit interconnecting node 508 is a common node of the series connected resistor R1 and capacitor C2.

There is also a second circuit 510 with a second circuit interconnecting node 512. Again, by way of example, the second circuit 510 is formed from a third capacitor C3 across the second circuit interconnecting node 512 and the analog circuit node 504, and a series connected resistor R2 and a capacitor C4 also are coupled across the second circuit interconnecting node 512 and the analog circuit node 304. In this embodiment the second circuit interconnecting node 512 is a common node of the series connected resistor R2 and third Capacitor C3.

The analog circuit 500 provides selective connecting of the first circuit interconnecting node 508 to the second circuit interconnecting node 512. In this regard, the first node 502 is coupled to the first circuit interconnecting node 508 and the second node 504 is coupled to the second circuit interconnecting node 512. However, it will be appreciated that the analog circuit 500 can be replaced, for instance, with the semiconductor switch 200 or with either of the semiconductor isolating circuits 300, 400.

Advantageously, the present invention reduces leakage currents in semiconductor switches and is especially useful, but not necessarily limited to, reducing such leakage currents in analogue circuit applications.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor isolating switch, comprising:
a first node;
a second node;
a switch control node;
two series connected primary Field Effect Transistors (FETs), wherein a first one the primary FETs is coupled between the first node and an intermediate node, and a second one of the primary FETs is coupled between the intermediate node and the second node;
a controllable pull-up FET coupled in series to a controllable pull-down FET, wherein the controllable pull-up FET is coupled between a power rail node and a common node and the controllable pull-down FET is coupled between the common node and a ground rail node; and
a leakage control transistor coupled between the common node and the intermediate node, wherein the primary FETs, the controllable pull-up FET, the controllable pull-down FET, and the leakage control transistor each have a respective gate electrode coupled to the switch control node.

2. The semiconductor isolating switch of claim 1, wherein a source electrode of the first one the primary FETs is coupled to the intermediate node and a drain electrode of the second one of the primary FETs is coupled to the intermediate node.

3. The semiconductor isolating switch of claim 2, wherein the two series connected primary FETs and the controllable pull-down FET are N-type transistors, and the controllable pull-up FET and leakage control transistor are both P-type transistors.

4. The semiconductor isolating switch of claim 3, wherein a source electrode of the leakage control transistor is coupled to the common node.

5. The semiconductor isolating switch of claim 4, wherein a respective drain electrode of the controllable pull-up FET and the controllable pull-down FET are coupled to the common node.

6. The semiconductor isolating switch of claim 5, wherein in operation when a control signal at the switch control node is at a ground potential the pull-up FET and the leakage control transistor couple the intermediate node to a supply potential, thereby controlling the first one the primary FETs to be in a non-conductive state.

7. The semiconductor isolating switch of claim 2, wherein the two series connected primary FETs and the controllable pull-up FET are P-type transistors, and the controllable pull-down FET and the leakage control transistor are both N-type transistors.

8. The semiconductor isolating switch of claim 7, wherein a source electrode of the leakage control transistor is coupled to the common node.

9. The semiconductor isolating switch of claim 8, wherein a respective drain electrode of the controllable pull-up FET and the controllable pull-down FET are coupled to the common node.

10. The semiconductor isolating switch of claim 9, wherein in operation when a control signal at the switch control node is at a supply potential the pull-down FET and the leakage control transistor couple the intermediate node to a ground potential, thereby controlling the first one the primary FETs to be in a non-conductive state.

11. An analog circuit, comprising:
a first circuit with a first circuit interconnecting node;
a second circuit with a second circuit interconnecting node; and
a semiconductor switch for selectively connecting the first circuit interconnecting node to the second circuit interconnecting node, wherein the semiconductor isolating switch includes:
a first node coupled to the first circuit interconnecting node;
a second node coupled to the second circuit interconnecting node;
a switch control node;
two series connected primary field effect transistors (FETs), wherein a first one the primary FETs is coupled between the first node and an intermediate node, and a second one of the primary FETs is coupled between the intermediate node and the second node;
a controllable pull-up FET coupled in series to a controllable pull-down FET, wherein the controllable pull-up FET is coupled between a power rail node and a common node and the controllable pull-down FET is coupled between the common node and a ground rail node; and
a leakage control transistor coupled between the common node and intermediate node, wherein the primary FETs, the controllable pull-up FET, the controllable pull-down FET, and the leakage control transistor each have a respective gate electrode coupled to the switch control node.

12. The analog circuit of claim 11, wherein a source electrode of the first one the primary FETs is coupled to the intermediate node and a drain electrode of the second one of the primary FETs is coupled to the intermediate node.

13. The analog circuit of claim 12, wherein the two series connected primary FETs and the controllable pull-down FET are N-type transistors, and the controllable pull-up FET and the leakage control transistor are both P-type transistors.

14. The analog circuit of claim 13, wherein a source electrode of the leakage control transistor is coupled to the common node, and a respective drain electrode of the controllable pull-up FET and the controllable pull-down FET are coupled to the common node.

15. The analog circuit of claim 12, wherein the two series connected primary FETs and the controllable pull-up FET are P-type transistors, and the controllable pull-down FET and the leakage control transistor are N-type transistors.

16. The analog circuit of claim 15, wherein a source electrode of the leakage control transistor is coupled to the common node.

17. The analog circuit of claim 16, wherein a respective drain electrode of the controllable pull-up FET and the controllable pull-down FET are coupled to the common node.

18. A semiconductor isolating circuit having two complementary semiconductor isolating switches, wherein each of the switches comprises:
a first node;
a second node;
a switch control node;
a ground rail node;
a power rail node;
two series connected primary field effect transistors (FETs), wherein a first one the primary FETs is coupled between the first node and an intermediate node, and a second one of the primary FETs is coupled between the intermediate node and the second node;
a controllable pull-up FET coupled in series to a controllable pull-down FET, wherein the controllable pull-up FET is coupled between the power rail node and a common node and the controllable pull-down FET is coupled between the common node and the ground rail node; and
a leakage control transistor coupled between the common node and the intermediate node, wherein the primary FETs, the controllable pull-up FET, the controllable pull-down FET and the leakage control transistor each have a respective gate electrode coupled to the switch control node,
wherein the first nodes of each of the switches are coupled together, the second nodes of each of the switches are coupled together and the switch control nodes of each of the switches are coupled together by way of an inverter, and
wherein each of the transistors of a first one of the switches is complementary relative to a respective transistor of a second one of the switches.

19. The semiconductor isolating circuit of claim 18, wherein the two series connected primary FETs and the controllable pull-down FET of the first one of the switches are N-type transistors, and the two series connected primary FETs and the controllable pull-up FET of the second one of the switches are P-type transistors.

20. The semiconductor isolating circuit of claim 19, wherein the controllable pull-up FET and the leakage control transistor of the first one of the switches are P-type transistors and the controllable pull-down FET and the leakage control transistor of the second one of the switches are N-type transistors.
